(19) United States
(12) Patent Application Publication
(10) Pub. No.: US 2025/0087552 A1
(43) Pub. Date: Mar. 13, 2025

(54) SEMICONDUCTOR DEVICE

(71) Applicant: Murata Manufacturing Co., Ltd., Kyoto-fu (JP)

(72) Inventors: Mari SAJI, Nagaokakyo-shi (JP); Atsushi KUROKAWA, Nagaokakyo-shi (JP); Hiroshi YAMADA, Nagaokakyo-shi (JP)

(73) Assignee: Murata Manufacturing Co., Ltd., Kyoto-fu (JP)

(21) Appl. No.: 18/963,083

(22) Filed: Nov. 27, 2024

Related U.S. Application Data
(63) Continuation of application No. PCT/JP2023/024810, filed on Jul. 4, 2023.

(30) Foreign Application Priority Data
Jul. 14, 2022 (JP) 2022-113100

(51) Int. Cl. H01L 23/373; H01L 23/00; H01L 27/12

(52) U.S. Cl. CPC H01L 23/3732; H01L 24/14; H10D 86/40; H10D 86/60; H01L 2224/1413

(57) ABSTRACT

At least one of transistors is in a device layer. A plurality of bumps are on one surface of the device layer. An insulating layer is on a surface of the device layer opposite to the surface having the plurality of bumps. The heat transfer layer is in contact with a surface of the insulating layer opposite to a surface on which the device layer is disposed. The heat transfer layer is formed of an insulating material having a thermal conductivity higher than a thermal conductivity of the insulating layer. When the device layer is viewed in plan view, one first transistor of the transistors includes a non-overlapping portion which is a portion not overlapping with the plurality of bumps, and the heat transfer layer is continuous from a portion overlapping with the non-overlapping portion to a portion overlapping with at least one of the plurality of bumps.

### CROSS-REFERENCE TO RELATED APPLICATIONS

This application claims benefit of priority to International Patent Application No. PCT/JP2023/024810, filed Jul. 4, 2023, and to Japanese Patent Application No. 2022-113100, filed Jul. 14, 2022, the entire contents of each are incorporated herein by reference.

### BACKGROUND

### Technical Field

The present disclosure relates to a semiconductor device.

### Background Art

In a device using an SOI substrate, in which an insulating layer and a semiconductor layer are laminated on a support substrate made of semiconductors, parasitic capacitance between the semiconductor layer and the support substrate may prevent improvement in device characteristics. A semiconductor module in which a device using an SOI substrate is flip-chip mounted on a module substrate, and the like, and then the support substrate is removed to reduce parasitic capacitance is known as described, for example, in International Publication No. 2019/163580.

### SUMMARY

Heat generated by the transistors formed in the semiconductor layer is considered to be conducted to the module substrate mainly through the nearest bump. However, in semiconductor modules with a structure in which devices using SOI substrates are flip-chip mounted on a module substrate and then the support substrate is removed, compared to the configuration in which the support substrate is left in place, the temperature of the transistors formed in the semiconductor layer is more likely to rise during operation of the transistors. Excessive transistor temperature rise may degrade transistor characteristics. For example, if a transistor is used as a switch, the insertion loss of the switch increases.

Accordingly, the present disclosure provides a semiconductor device capable of suppressing an increase in parasitic capacitance between a device layer including a semiconductor layer and a multilayer wiring layer on which a transistor is formed and other layers, and suppressing a temperature rise of the transistor.

According to one aspect of the present disclosure, a semiconductor device includes a device layer in which at least one of transistors is formed, a plurality of bumps that are provided on one surface of the device layer, an insulating layer that is disposed on a surface of the device layer opposite to the surface on which the plurality of bumps are provided, and a heat transfer layer that is in contact with a surface of the insulating layer opposite to a surface on which the device layer is disposed, and is formed of an insulating material having a thermal conductivity higher than a thermal conductivity of the insulating layer. When the device layer is viewed in plan view, one first transistor of the transistors includes a non-overlapping portion which is a portion not overlapping with the plurality of bumps, and the heat transfer layer is continuously disposed from a portion overlapping with the non-overlapping portion to a portion overlapping with at least one of the plurality of bumps.

Since the heat transfer layer facing the device layer with the insulating layer interposed therebetween is formed of insulating material, the parasitic capacitance generated in the device layer is reduced. In addition, the heat transfer layer functions as a heat transfer path from the transistor to the bumps, thus suppressing the temperature rise of the transistor.

### BRIEF DESCRIPTION OF THE DRAWINGS

FIG. 1 is a schematic view showing a planar positional relationship between the respective constituent elements of a semiconductor device according to a first embodiment;

FIG. 2 is a cross-sectional view of a part of the semiconductor device according to the first embodiment;

FIGS. 3A, 3B, and 3C are cross-sectional views of the semiconductor device according to the first embodiment in the middle of manufacturing;

FIG. 4A is a diagram showing a positional relationship between a transistor of the semiconductor device and a plurality of bumps in plan view according to the first embodiment, and FIG. 4B is a schematic perspective view of a state where the semiconductor device is mounted on a module substrate;

FIG. 5A is a schematic cross-sectional view of the semiconductor device and the module substrate according to the first embodiment, and FIG. 5B is a schematic cross-sectional view of a semiconductor device and a module substrate according to a comparative example;

FIGS. 6A and 6B are schematic views showing results of simulating a temperature distribution in the semiconductor device in which a heat transfer layer is not disposed and the semiconductor device in which a heat transfer layer is disposed, respectively;

FIGS. 7A and 7B are diagrams showing a planar positional relationship between a plurality of constituent elements of a semiconductor device according to a modification of the first embodiment;

FIG. 8 is a schematic cross-sectional view of a semiconductor device and a module substrate according to a second embodiment;

FIG. 9 is a graph showing the simulation results of a relationship between the maximum achievable temperature and the thickness of the heat transfer layer when the transistor of the semiconductor device according to the second embodiment is operated;

FIG. 10 is a graph showing the simulation results of a relationship between the maximum achievable temperature and the thermal conductivity of the heat transfer layer when the transistor of the semiconductor device according to the second embodiment is operated;

FIG. 11A is a diagram showing a positional relationship in plan view between a transistor and a plurality of bumps in a semiconductor device according to a third embodiment, and FIG. 11B is a schematic cross-sectional view of the semiconductor device and a module substrate according to the third embodiment; and

FIG. 12 is a block diagram of a high-frequency module according to a fourth embodiment.

### DETAILED DESCRIPTION

### First Embodiment

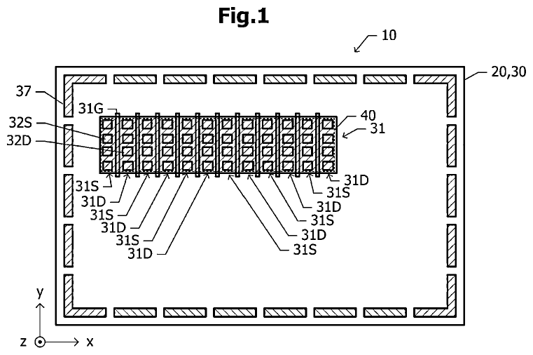

A semiconductor device according to a first embodiment will be described with reference to the drawings of FIGS. 1 to 6B.

FIG. 1 is a schematic view showing a planar positional relationship between the respective constituent elements of a semiconductor device 10 according to the first embodiment. An insulating layer 20 and a device layer 30 are disposed to substantially overlap with each other in plan view. A transistor 31 is disposed in an inner region of the device layer 30.

The transistor 31 is, for example, a multi-finger type field effect transistor (FET), and includes a plurality of source regions 31S, a plurality of drain regions 31D, and a plurality of gate electrodes 31G. The plurality of source regions 31S and the plurality of drain regions 31D are arranged alternately in one direction in the active region. A plane parallel to the surface of the device layer 30 is defined as an xy plane, and an xyz orthogonal coordinate system is defined in which a direction in which the plurality of source regions 31S and the plurality of drain regions 31D are arranged is defined as an x direction. The gate electrodes 31G are disposed between the source regions 31S and the drain regions 31D adjacent to each other.

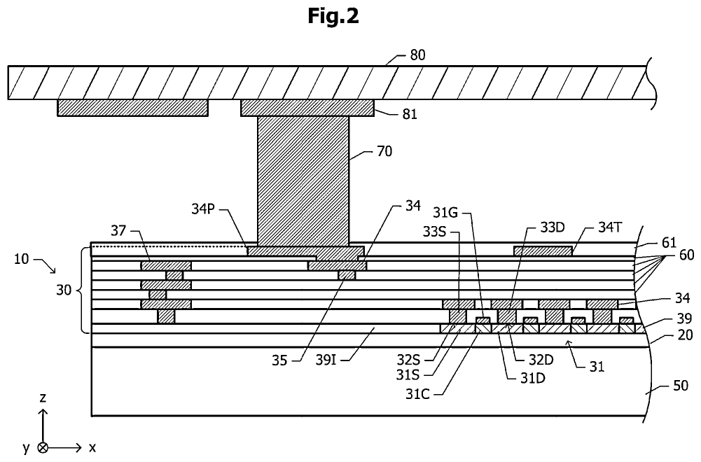

In plan view, a plurality of source contact regions 32S arranged in the y direction are defined inside each of the plurality of source regions 31S. Similarly, a plurality of drain contact regions 32D arranged in the y direction are defined inside each of the plurality of drain regions 31D. Here, the source contact region 32S means a region where the source region 31S and a source contact electrode (described later with reference to FIG. 2) are in ohmic contact with each other, and the drain contact region 32D means a region where the drain region 31D and a drain contact electrode (described later with reference to FIG. 2) are in ohmic contact with each other. The term “in plan view” means when the device layer 30 in which the transistor 31 is disposed is viewed in plan view from the direction in which the insulating layer 20 and the device layer 30 are laminated.

A high-frequency circuit is composed of the transistor 31 and a wiring line (not shown in FIG. 1). Examples of the high-frequency circuit include a low-noise amplifier that amplifies a high-frequency signal, a switch that selects one from a plurality of duplexers, filters, or the like provided for each frequency band, and the like.

In plan view, a rectangle having the smallest area and including all of the plurality of source contact regions 32S and the plurality of drain contact regions 32D is referred to as a minimum enclosing rectangle 40. In FIG. 1, the broken line indicates an outer peripheral line of the minimum enclosing rectangle 40, and hatching is added to the inside of the minimum enclosing rectangle 40. The region inside the minimum enclosing rectangle 40 can be considered as a region that substantially operates as the transistor 31.

A metal layer 37 is disposed slightly inside the outer peripheral line of the device layer 30 to surround the internal region of the device layer 30 in plan view. The metal layer 37 is also called a guard ring. The metal layer 37 is isolated into a plurality of portions in the circumferential direction. The metal layer 37 may be configured to be continuous in the circumferential direction such that the metal layer 37 has a closed annular shape in plan view.

FIG. 2 is a cross-sectional view of a part of the semiconductor device 10 and a module substrate 80 on which the semiconductor device 10 is mounted according to the first embodiment.

The semiconductor device 10 according to the first embodiment includes a device layer 30, an insulating layer 20, a heat transfer layer 50, and a plurality of bumps 70. In FIG. 2, one of the plurality of bumps 70 is shown. The semiconductor device 10 is flip-chip mounted on the module substrate 80. A direction from the semiconductor device 10 to the module substrate 80 is defined as an upward direction.

The device layer 30 is disposed on a surface of the insulating layer 20 facing upward, and the heat transfer layer 50 is disposed on a surface of the insulating layer 20 facing downward. The device layer 30 includes an element formation layer 39 made of a semiconductor and in contact with the insulating layer 20, and a multilayer wiring layer disposed on the element formation layer 39. The insulating layer 20 may be composed of a single layer or may be composed of a plurality of layers. For example, in a case where the insulating layer 20 is composed of a single layer, silicon oxide is used as a material of the insulating layer 20. In a case where the insulating layer 20 is composed of a plurality of layers, for example, silicon oxide or silicon nitride is used as a material of each layer. The element formation layer 39 is composed of an active region made of silicon and an insulating element isolation region 39I surrounding the active region. The plurality of source regions 31S, the plurality of drain regions 31D, and a plurality of channel regions 31C of the transistor 31 are disposed in the active region of the element formation layer 39.

The plurality of source regions 31S and the plurality of drain regions 31D are disposed in a row in the x direction at intervals. The channel region 31C is defined between the source region 31S and the drain region 31D adjacent to each other. The gate electrode 31G is disposed on the channel region 31C with a gate insulating film (not shown) interposed therebetween.

The multilayer wiring layer on the element formation layer 39 includes a plurality of insulating layers 60. For the plurality of insulating layers 60, for example, a low dielectric constant material (Low-k material) is used. SiN or an organic insulating material is used for the uppermost insulating layer 60.

The source contact electrodes 33S and the drain contact electrodes 33D are embedded in the via holes provided in the lowermost insulating layer 60 of the multilayer wiring layer. The source contact electrode 33S is in ohmic contact with the source region 31S in the source contact region 32S, and the drain contact electrode 33D is in ohmic contact with the drain region 31D in the drain contact region 32D. The source contact electrode 33S and the drain contact electrode 33D are formed of, for example, W. A close-contact layer such as TiN may be disposed as necessary for the purpose of improving close contact. A film made of metal silicide such as CoSi and NiSi may be formed on each of the surfaces of the source region 31S and the drain region 31D to form a structure for reducing the resistance of the contact portion.

A plurality of wiring lines 34 or a plurality of vias 35 are disposed in each of the plurality of insulating layers 60 which are the second or subsequent layers. For the formation of the wiring line 34 or the via 35, a damascene method, a dual damascene method, or a subtractive method is used. A plurality of wiring lines 34T and a plurality of pads 34P are disposed in the uppermost wiring layer of the device layer 30. As an example, the wiring lines 34 and 34T and the pad 34P are formed of Cu or Al, and the via is formed of Cu or W. As necessary, a close-contact layer such as TiN may be disposed for the purpose of preventing diffusion or improving close contact. The metal layer 37 called a guard ring is disposed in a peripheral edge portion of the multilayer wiring layer.

A protective film 61 made of an organic insulating material is disposed on the device layer 30 to cover the uppermost layer wiring line 34T and the pad 34P. Examples of the organic insulating material used for the protective film 61 include polyimide and benzocyclobutene (BCB). A plurality of openings exposing the upper surface of each of the plurality of pads 34P are provided in the protective film 61, and the bump 70 is disposed on the pad 34P in the opening. The bump 70 is composed of, for example, an under bump metal layer, a Cu pillar, and a solder layer. A structure other than the above-described structure may be used as the bump 70.

The bump 70 is connected to a land 81 of the module substrate 80, whereby the semiconductor device 10 is flip-chip mounted on the module substrate 80. After mounting the semiconductor device 10 on the module substrate 80, the semiconductor device 10 may be sealed with a resin.

The heat transfer layer 50 is formed of an insulating material having a thermal conductivity higher than the thermal conductivity of the insulating layer 20, for example, diamond-like carbon (DLC). In a case where the heat transfer layer 50 is formed of DLC, for example, in a case where XPS analysis is performed on a surface (surface in contact with the heat transfer layer 50) downward-facing the insulating layer 20, a peak of sp3 is detected in the spectrum analysis of carbon. In addition, the heat transfer layer 50 is thermally coupled to the insulating layer 20, and heat is efficiently conducted between the insulating layer 20 and the heat transfer layer 50. The material of the heat transfer layer 50 is not limited to DLC. For example, the heat transfer layer 50 may contain a material such as alumina (including sapphire), aluminum nitride, or boron nitride. The thermal conductivity of these materials is as shown in the following table, for example.

TABLE 1

| | Thermal Conductivity |
|---|---|
| Material | [W/m · K] |
| DLC | 1000 |
| Alumina (including sapphire) | 42 |
| Aluminum nitride | 320 |
| Boron nitride | 410 |

The thickness of the heat transfer layer 50 is, for example, 75 nm, the thickness of the device layer 30 is, for example, 75 nm, and the thickness of the bump 70 is, for example, 160 μm. The thickness of the insulating layer 20 is, for example, 200 nm or more and 800 nm or less (i.e., from 200 nm to 800 nm).

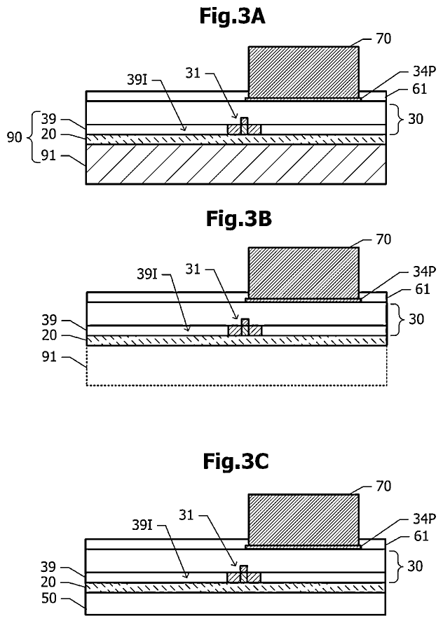

Next, a manufacturing method of the semiconductor device 10 according to the first embodiment will be described with reference to FIGS. 3A, 3B, and 3C. FIGS. 3A, 3B, and 3C are cross-sectional views of the semiconductor device 10 according to the first embodiment in the middle of manufacturing.

As shown in FIG. 3A, an SOI substrate 90 including a temporary support substrate 91 made of silicon, the insulating layer 20 made of silicon oxide, and the element formation layer 39 made of silicon is prepared. The element isolation region 39I is formed in a part of the element formation layer 39, and the transistor 31 is formed in the active region. In FIG. 3A, one source region 31S, one drain region 31D, and one gate electrode 31G are shown. Further, a multilayer wiring layer of the device layer 30 is formed on the element formation layer 39.

The protective film 61 made of an organic insulating material is formed on the device layer 30, and a bump 70 is further formed. These structures can be formed by using a general semiconductor wafer process.

As shown in FIG. 3B, the temporary support substrate 91 is etched and removed. Before etching and removing the temporary support substrate 91, a protective material (not shown) or the like is affixed to the surface opposite to the temporary support substrate 91. By removing the temporary support substrate 91, one surface of the insulating layer 20 is exposed. As an example, in the state shown in FIG. 3A, the thickness of the insulating layer 20 is 400 nm or more and 1000 nm or less (i.e., from 400 nm to 1000 nm). However, since the exposed surface layer portion of the insulating layer 20 is also etched by etching of the temporary support substrate 91, the thickness of the insulating layer 20 is 200 nm or more and 800 nm or less (i.e., from 200 nm to 800 nm).

As shown in FIG. 3C, the heat transfer layer 50 is formed on the exposed surface of the insulating layer 20. The heat transfer layer 50 is formed of, for example, DLC. For the film formation of the heat transfer layer 50, for example, a plasma chemical vapor deposition (P-CVD) using a hydrocarbon-based gas or sputtering using a solid carbon target can be used. After forming the heat transfer layer 50, the laminated structure from the heat transfer layer 50 to the protective film 61 is cut with a dicing machine to form individual pieces.

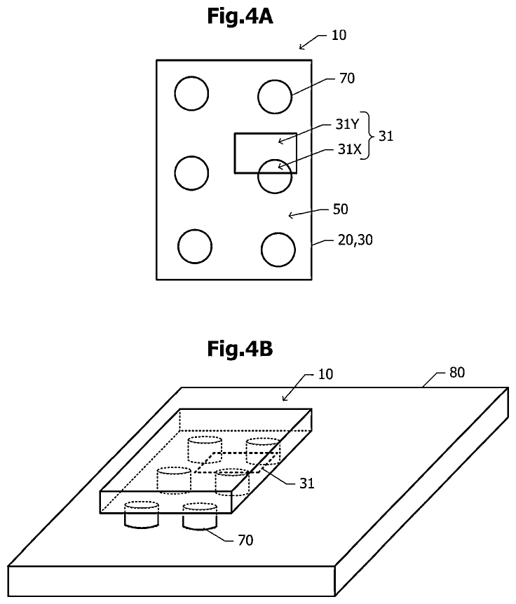

FIG. 4A is a diagram showing a positional relationship between the transistor 31 of the semiconductor device 10 and the plurality of bumps 70 in plan view according to the first embodiment, and FIG. 4B is a schematic perspective view of a state where the semiconductor device 10 is mounted on the module substrate 80. In addition to the transistor 31, a plurality of transistors are disposed in the element formation layer 39 (FIG. 2) of the semiconductor device 10. The heat transfer layer 50 is disposed over the entire region of the insulating layer 20 and the device layer 30 in plan view.

The plurality of bumps 70 of the semiconductor device 10 are connected to the module substrate 80. In plan view, a portion of the transistor 31 overlaps with one bump 70, and the other portion does not overlap with any bump 70. The fact that a portion of the transistor 31 overlaps with the other portion in plan view means that the minimum enclosing rectangle 40 shown in FIG. 1 overlaps with the other portion.

A portion of the transistor 31 overlapping with the bump 70 is referred to as an overlapping portion 31X, and a portion not overlapping with the bump 70 is referred to as a non-overlapping portion 31Y. In plan view, an area of the non-overlapping portion 31Y is larger than an area of the overlapping portion 31X. In a case where the semiconductor device 10 is operated, the transistor 31 becomes a main heat source.

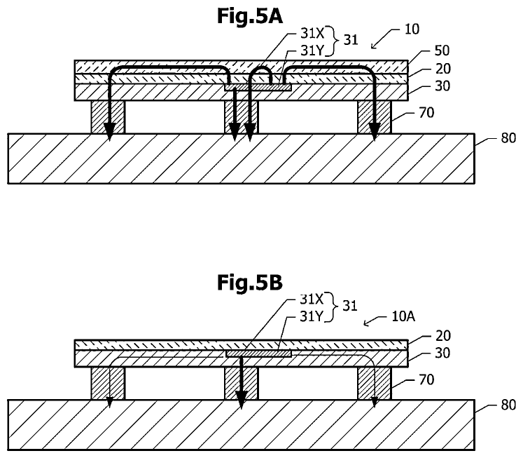

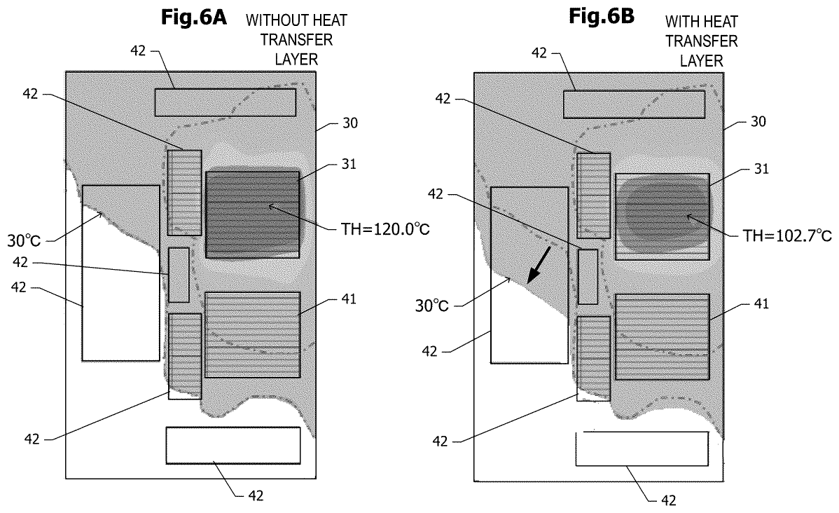

Next, excellent effects of the first embodiment will be described with reference to the views from FIGS. 5A to 6B.

FIG. 5A is a schematic cross-sectional view of the semiconductor device 10 and the module substrate 80 according to the first embodiment, and FIG. 5B is a schematic cross-sectional view of the semiconductor device 10A and the module substrate 80 according to a comparative example. In the semiconductor device 10A according to the comparative example, the heat transfer layer 50 (FIG. 5A) is not disposed. In any of the semiconductor devices 10 and 10A, the plurality of bumps 70 are connected to the module substrate 80, whereby the semiconductor devices 10 and 10A are mounted on the module substrate 80. The arrows shown in FIGS. 5A and 5B indicate main heat transfer paths through which the heat generated in the transistor 31 is conducted to the module substrate 80.

In the configuration in which the support substrate 91 (FIG. 3A) made of silicon is left, the problem due to the temperature rise of the transistor 31 is not significant. Since the heat generated by the transistor 31 is conducted to the module substrate 80 through the nearest bump 70, it is considered that sufficient heat dissipation efficiency is achieved.

However, as shown in FIG. 5B, it was found by the inventors' experiments that the temperature rise of the transistor 31 is remarkable when the support substrate 91 (FIG. 3A) is removed. The phenomenon in which the heat generated in the transistor 31 is conducted to the module substrate 80 through the nearest bump 70 is also common in the comparative example shown in FIG. 5B. It is considered that sufficient heat dissipation efficiency can be obtained in a configuration in which the support substrate 91 is left because the support substrate 91 also functions as a heat transfer path. That is, the heat generated in the transistor 31 is diffused in the in-plane direction of the support substrate 91 through the support substrate 91, which is in contact with the insulating layer 20, and is conducted to the bump 70.

In a case where the support substrate 91 (FIG. 3A) is removed as shown in FIG. 5B, the heat generated in the transistor 31 is less likely to be diffused in the in-plane direction. The heat generated in the overlapping portion 31X of the transistor 31 is mainly conducted to the module substrate 80 through the bump 70, which overlaps with the overlapping portion 31X of the transistor 31 in plan view. However, the heat generated in the non-overlapping portion 31Y of the transistor 31 is less likely to be conducted to the nearest bump 70. As a result, it is considered that the temperature rise of the non-overlapping portion 31Y of the transistor 31 is remarkable.

In the semiconductor device 10 according to the first embodiment shown in FIG. 5A, the heat generated in the non-overlapping portion 31Y of the transistor 31 is mainly conducted to the bump 70 that overlaps with the transistor 31 through the heat transfer layer 50. Further, the heat generated in the transistor 31 is diffused in the in-plane direction through the heat transfer layer 50 and is also conducted to the bump 70 that does not overlap with the transistor 31.

In the first embodiment, the heat transfer layer 50 having a higher thermal conductivity than the insulating layer 20 and the bump 70 not overlapping with the transistor 31 in plan view function as a heat transfer path from the transistor 31 to the module substrate 80. In addition, the heat generated in the non-overlapping portion 31Y of the transistor 31 is also diffused in the in-plane direction in the heat transfer layer 50 and is conducted to the bump 70. Therefore, the heat dissipation efficiency from the transistor 31 is improved, and the temperature rise of the transistor 31 can be suppressed.

As described above, the heat transfer layer 50 has a function of reducing the thermal resistance from the non-overlapping portion 31Y of the transistor 31 to the bump 70. Therefore, in a case where the area of the non-overlapping portion 31Y of the transistor 31 is larger than the area of the overlapping portion 31X, the effect of disposing the heat transfer layer 50 is further enhanced.

Further, since the heat transfer layer 50 is formed of an insulating material, the parasitic capacitance generated in the device layer 30 is reduced as compared with a configuration in which a support substrate made of silicon or the like is used instead of the heat transfer layer 50. Therefore, the deterioration of the high-frequency characteristics of the semiconductor device 10 is suppressed.

Next, with reference to FIGS. 6A and 6B, a result of simulating the temperature distribution in the in-plane direction in a case where the transistor 31 is used as a heat source in a configuration in which the heat transfer layer 50 (FIG. 5A) is disposed and a configuration in which the heat transfer layer 50 is not disposed will be described. FIGS. 6A and 6B are schematic views showing results of simulating a temperature distribution in a semiconductor device in which the heat transfer layer 50 is not disposed and a semiconductor device in which the heat transfer layer 50 is disposed, respectively.

The transistor 31, another transistor 41, and a plurality of transistors 42 are disposed in the device layer 30. The transistors 31 and 41 are multi-finger type transistors having substantially the same shape. In the semiconductor device to be simulated, bumps are not provided. In addition, the thickness and the thermal conductivity of the heat transfer layer 50 were set to 50 nm and 1,000 W/m·K, respectively. This thermal conductivity corresponds to, for example, the thermal conductivity of diamond-like carbon. The thickness and the thermal conductivity of the insulating layer 20 were set to 200 nm and 1.4 W/m·K, respectively. This thermal conductivity corresponds to, for example, a thermal conductivity of silicon oxide. The thickness and the thermal conductivity of the device layer 30 were set to 75 nm and 150 W/m·K, respectively. This thermal conductivity corresponds to, for example, a thermal conductivity of silicon. A high-frequency signal of 0.1 W was supplied to the transistor 31.

In this simulation, the temperature distribution was calculated in a case where the transistor 31 is a heat source. In FIGS. 6A and 6B, the height of the maximum achievable temperature is represented by the gray density, which means that the temperature is higher in a region of relatively denser gray. A maximum achievable temperature TH in the semiconductor device (FIG. 6A) in which the heat transfer layer 50 was not disposed was 120° C., and the maximum achievable temperature TH in the semiconductor device (FIG. 6B) in which the heat transfer layer 50 was disposed was 102.7° C.

The temperature of the white region is 30° C. or lower. That is, the boundary line between the gray region and the white region represents an isotherm at a temperature of 30° C. It can be seen that, when the heat transfer layer 50 is disposed, the region where the temperature is 30° C. or lower is narrowed. In addition, in the semiconductor device in which the heat transfer layer 50 is not disposed, the outer shape of the dark gray region substantially matches the outer shape of the transistor 31. This means that the heat generated in the transistor 31 remains in the transistor 31. In the semiconductor device in which the heat transfer layer 50 is disposed, the temperature of the region near the four corners of the transistor 31 is lower than that of the semiconductor device in which the heat transfer layer 50 is not disposed. This means that the heat generated in the transistor 31 is diffused in the in-plane direction.

From the simulation results shown in FIGS. 6A and 6B, it can be seen that the maximum achievable temperature is lowered and the heat generated by the transistor 31 is likely to be diffused in the in-plane direction by disposing the heat transfer layer 50.

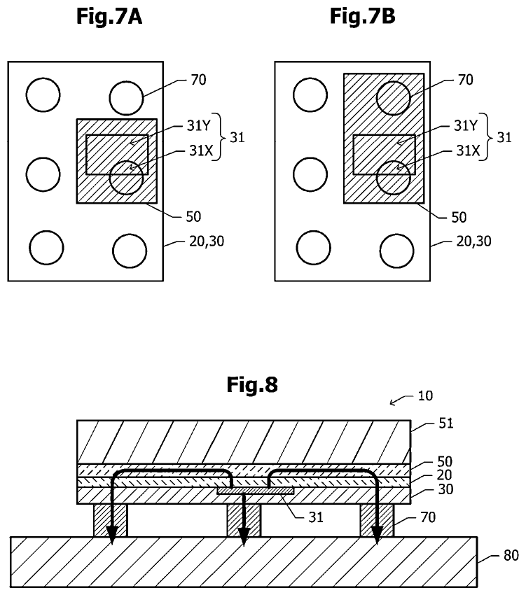

Next, a semiconductor device according to a modification of the first embodiment will be described with reference to FIGS. 7A and 7B. FIGS. 7A and 7B are diagrams showing a planar positional relationship between a plurality of constituent elements of the semiconductor device 10 according to the modification of the first embodiment. In FIGS. 7A and 7B, the region where the heat transfer layer 50 is disposed is hatched. In the first embodiment (FIG. 4A), the heat transfer layer 50 is disposed in the entire region of the device layer 30. On the other hand, in the modifications shown in FIGS. 7A and 7B, the heat transfer layer 50 is disposed only in a part of the region of the device layer 30.

In the modification shown in FIG. 7A, the heat transfer layer 50 includes, in plan view, the transistor 31, and one bump 70 overlapping with the transistor 31. The heat generated in the non-overlapping portion 31Y of the transistor 31 is conducted to the bump 70 overlapping with the transistor 31 through the heat transfer layer 50. Therefore, the heat dissipation efficiency of the heat generated in the non-overlapping portion 31Y can be improved.

In the modification shown in FIG. 7B, the heat transfer layer 50 includes, in plan view, the transistor 31, the bump 70 overlapping with the transistor 31, and one bump 70 not overlapping with the transistor 31. The heat generated in the overlapping portion 31X and the non-overlapping portion 31Y of the transistor 31 is conducted to the two bumps 70 through the heat transfer layer 50. Therefore, the heat dissipation efficiency from the transistor 31 can be further improved as compared with the modification shown in FIG. 7A.

As in the modification shown in FIGS. 7A and 7B, the heat transfer layer 50 does not necessarily need to be disposed over the entire region of the device layer 30. In particular, in order to improve the heat dissipation efficiency from the non-overlapping portion 31Y of the transistor 31, the heat transfer layer 50 may be continuously disposed from a region overlapping with the non-overlapping portion 31Y to a portion overlapping with at least one of the plurality of bumps 70. In FIGS. 7A and 7B, the heat transfer layer 50 includes one or two bumps 70 in plan view, but the heat transfer layer 50 may be configured to overlap with a portion of each of one or the plurality of bumps 70. That is, the configuration in which “the heat transfer layer 50 overlaps with the bump 70” includes a configuration in which the heat transfer layer 50 includes at least one bump 70 in plan view and a configuration in which the heat transfer layer 50 overlaps with a portion of one bump 70.

Although the transistor 31 (FIG. 2) disposed in the semiconductor device 10 according to the first embodiment is a MOSFET, the transistor 31 may be a bipolar transistor. In a case where the transistor 31 is a bipolar transistor, the minimum enclosing rectangle including the emitter region, the base region, and the collector region in plan view may be considered as a region where the transistor 31 is disposed.

### Second Embodiment

Next, a semiconductor device according to a second embodiment will be described with reference to FIGS. 8, 9, and 10. Configurations common to the semiconductor device according to the first embodiment described with reference to the drawings of FIGS. 1 to 6B will not be described below.

FIG. 8 is a schematic cross-sectional view of the semiconductor device 10 and the module substrate 80 according to the second embodiment. The configuration including the heat transfer layer 50, the insulating layer 20, the device layer 30, and the plurality of bumps 70 is the same as the configuration of the semiconductor device 10 (FIG. 5A) according to the first embodiment. The semiconductor device 10 according to the second embodiment further includes a support substrate 51 disposed on a surface of the heat transfer layer 50 opposite to the surface facing the insulating layer 20 side. The support substrate 51 is formed of an insulating material having a thermal conductivity lower than that of the heat transfer layer 50.

The thickness of the support substrate 51 is larger than the total thickness of the device layer 30, the insulating layer 20, and the heat transfer layer 50. As the support substrate 51, for example, a resin substrate such as an epoxy resin is used. The support substrate 51 is attached to the heat transfer layer 50 by, for example, an adhesive. After the support substrate 51 is attached, cutting with a dicing machine is performed to form individual pieces.

Next, the excellent effects of the second embodiment will be described.

Even in the second embodiment, the heat generated by the transistor 31 is diffused in the in-plane direction through the heat transfer layer 50 as in the first embodiment. Therefore, the heat dissipation efficiency from the transistor 31 can be improved. Further, in the second embodiment, since the semiconductor device 10 is mechanically supported by the support substrate 51, an excellent effect that handling is easy in the manufacturing process can be obtained.

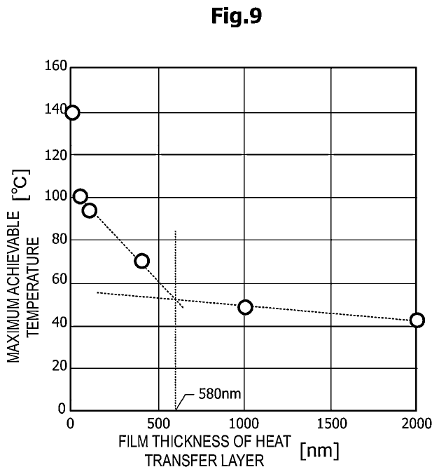

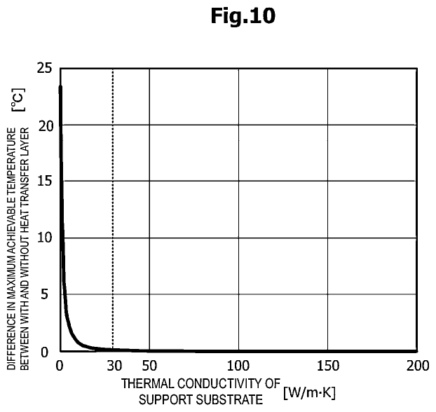

Next, a preferred thickness of the heat transfer layer 50 will be described with reference to FIG. 9. FIG. 9 is a graph showing simulation results of a relationship between the maximum achievable temperature and the thickness of the heat transfer layer 50 when the transistor 31 is operated. The horizontal axis represents the thickness of the heat transfer layer 50 in units of [nm], and the vertical axis represents the maximum achievable temperature of the transistor 31 in units of [° C.]. As simulation conditions, the thermal conductivity of the support substrate 51 was set to 0.25 W/m·K, the thickness of the support substrate 51 was set to 200 μm, and the thermal conductivity of the heat transfer layer 50 was set to 1000 W/m·K. The semiconductor device to be simulated is not provided with the bump 70. A high-frequency signal of 0.1 W was supplied to the transistor 31.

It can be seen that in the semiconductor device in which the heat transfer layer 50 is not provided, that is, the thickness of the heat transfer layer 50 is 0 nm, the maximum achievable temperature is about 140° C., whereas when the heat transfer layer 50 is disposed even slightly, the maximum achievable temperature is significantly reduced. In addition, as the thickness of the heat transfer layer 50 increases, the maximum achievable temperature decreases. When the thickness of the heat transfer layer 50 is 580 nm or more, the inclination of the maximum achievable temperature with respect to the thickness of the heat transfer layer 50 is gentle.

In other words, in the range where the thickness of the heat transfer layer 50 is less than 580 nm, the change in the maximum achievable temperature with respect to the change in the thickness of the heat transfer layer 50 is large, and in the range where the thickness of the heat transfer layer 50 is 580 nm or more, the change in the maximum achievable temperature with respect to the change in the thickness of the heat transfer layer 50 is small. In the configuration in which the thickness of the heat transfer layer 50 is less than 580 nm, if the thickness of the heat transfer layer 50 is less than a target thickness due to variations in the manufacturing process, the maximum achievable temperature is significantly increased. When the thickness of the heat transfer layer 50 is set to be 580 nm or more, even in a case where the thickness of the heat transfer layer 50 varies in the manufacturing process, the change in the maximum achievable temperature is small. In order to make the maximum achievable temperature less likely to be affected by the variation in the manufacturing process, it is preferable that the thickness of the heat transfer layer 50 is 580 nm or more.

In addition, from the simulation results shown in FIG. 9, it is confirmed that the effect that the maximum achievable temperature is less likely to be affected by the variation of the manufacturing process can be obtained when the thickness of the heat transfer layer 50 is in a range of 580 nm or more and 2000 nm or less (i.e., from 580 nm to 2000 nm).

Next, with reference to FIG. 10, a range of the thermal conductivity of the support substrate 51 in order to obtain a sufficient effect of providing the heat transfer layer 50 will be described.

FIG. 10 is a graph showing simulation results of a relationship between the maximum achievable temperature and the thermal conductivity of the heat transfer layer 50 when the transistor 31 is operated. The horizontal axis represents the thermal conductivity of the support substrate 51 in units of [W/m·K], and the vertical axis represents a difference in the maximum achievable temperature between the semiconductor device in which the heat transfer layer 50 is disposed and the semiconductor device in which the heat transfer layer 50 is not disposed in units of [° C.]. As simulation conditions, the thickness of the support substrate 51 was set to 200 μm, the thickness of the heat transfer layer 50 was set to 50 nm, and the thermal conductivity of the heat transfer layer 50 was set to 1000 W/m·K.

In the range where the thermal conductivity of the support substrate 51 is higher than 30 W/m·K, the insertion of the heat transfer layer 50 has little effect in reducing the maximum achievable temperature. This is because the support substrate 51 functions as a heat transfer path. In the range where the thermal conductivity of the support substrate 51 is 30 W/m·K or less, the insertion of the heat transfer layer 50 has the effect of reducing the maximum achievable temperature. Therefore, in a case where the thermal conductivity of the support substrate 51 is 30 W/m·K, a sufficient effect of disposing the heat transfer layer 50 can be obtained.

### Third Embodiment

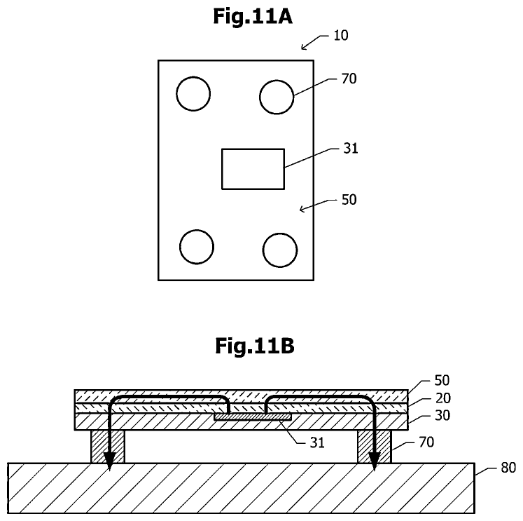

Next, a semiconductor device according to a third embodiment will be described with reference to FIGS. 11A and 11B. Configurations common to the semiconductor device according to the first embodiment described with reference to the drawings of FIGS. 1 to 6B will not be described below.

FIG. 11A is a diagram showing a positional relationship in plan view between the transistor 31 and a plurality of bumps 70 in the semiconductor device 10 according to the third embodiment, and FIG. 11B is a schematic cross-sectional view of the semiconductor device 10 and the module substrate 80 according to the third embodiment. In the semiconductor device 10 (FIG. 4A) according to the first embodiment, the transistor 31 that overlaps with the bump 70 in plan view. On the other hand, in the third embodiment, the transistor 31 does not overlap with any of the bumps 70 in plan view. As shown in FIG. 11B, the heat generated in the transistor 31 is conducted to the bump 70 through the heat transfer layer 50.

Next, the excellent effects of the third embodiment will be described.

Since the heat transfer layer 50 functions as a heat transfer path, the heat generated in the transistor 31 is dissipated through the bumps 70 which do not overlap with the transistor 31 in plan view as indicated by the arrows in FIG. 11B. Therefore, even in a configuration in which the transistor 31 does not overlap with any of the bumps 70 in plan view, the temperature rise of the transistor 31 can be suppressed.

When the bump 70 is disposed at a position overlapping with the transistor 31 in plan view, parasitic capacitance is generated between the transistor 31 and the bump 70. For example, in a case where the transistor 31 is used for a high-frequency switch or a high-frequency low-noise amplifier, characteristics of the high-frequency switch or the high-frequency low-noise amplifier are deteriorated due to the parasitic capacitance. In the third embodiment, since the transistor 31 does not overlap with the bump 70 in plan view, parasitic capacitance is hardly generated between the transistor 31 and the bump 70. Therefore, the deterioration in characteristics of the high-frequency switch or the high-frequency low-noise amplifier due to the parasitic capacitance is suppressed.

### Fourth Embodiment

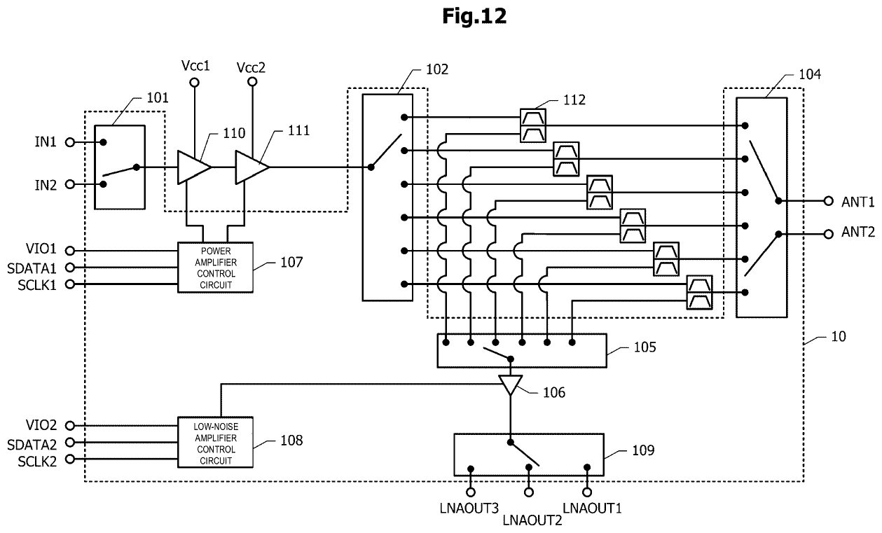

Next, a high-frequency module according to a fourth embodiment will be described with reference to FIG. 12. The high-frequency module according to the fourth embodiment includes the semiconductor device 10 according to any one of the first to third embodiments.

FIG. 12 is a block diagram of the high-frequency module according to the fourth embodiment. The high-frequency module according to the fourth embodiment includes the semiconductor device 10, a driver stage amplifier circuit 110, a power stage amplifier circuit 111, and a plurality of duplexers 112. The semiconductor device 10 includes an input switch 101, a band selection switch 102 for transmission, an antenna switch 104, a band selection switch 105 for reception, a low-noise amplifier 106, a power amplifier control circuit 107, a low-noise amplifier control circuit 108, and an output terminal selection switch 109 for reception. The high-frequency module has a function of performing transmission and reception in a frequency division duplex (FDD) system. In FIG. 12, the description of the impedance matching circuit to be inserted as necessary is omitted.

Two input-side contacts of the input switch 101 are connected to the respective high-frequency signal input terminals IN1 and IN2. High-frequency signals are input from the two high-frequency signal input terminals IN1 and IN2. When the input switch 101 selects one contact from the two input-side contacts, a high-frequency signal input to the selected contact is input to the driver stage amplifier circuit 110.

The high-frequency signal amplified by the driver stage amplifier circuit 110 is input to the power stage amplifier circuit 111. The high-frequency signal amplified by the power stage amplifier circuit 111 is input to an input-side contact of the band selection switch 102. In a case where the band selection switch 102 selects one contact from a plurality of output-side contacts, the high-frequency signal amplified by the power stage amplifier circuit 111 is output from the selected contact.

The plurality of output-side contacts of the band selection switch 102 are connected to respective input nodes for transmission of the plurality of duplexers 112 prepared for each band. A high-frequency signal is input to the duplexer 112 connected to an output-side contact selected by the band selection switch 102. The band selection switch 102 has a function of selecting one duplexer 112 from the plurality of duplexers 112 prepared for each band.

The antenna switch 104 has a plurality of circuit-side contacts and two antenna-side contacts. The plurality of circuit-side contacts of the antenna switch 104 are connected to respective input/output shared nodes of the plurality of duplexers 112. The two antenna-side contacts are connected to respective antenna terminals ANT1 and ANT2. Antennas are connected to the respective antenna terminals ANT1 and ANT2.

The antenna switch 104 connects the two antenna-side contacts to two respective contacts selected from the plurality of circuit-side contacts. In a case where the communication is performed using one band, the antenna switch 104 connects one circuit-side contact and one antenna-side contact. The high-frequency signal amplified by the power stage amplifier circuit 111 and passed through the duplexer 112 for a corresponding band is transmitted from an antenna connected to a selected antenna-side contact.

The band selection switch 105 for reception has six input-side contacts. Each of the six input-side contacts of the band selection switch 105 is connected to an output node for reception of the duplexer 112. An output-side contact of the band selection switch 105 is connected to the low-noise amplifier 106. A reception signal that has passed through the duplexer 112 connected to an input-side contact selected by the band selection switch 105 is input to the low-noise amplifier 106.

A circuit-side contact of the output terminal selection switch 109 is connected to an output node of the low-noise amplifier 106. Three terminal-side contacts of the output terminal selection switch 109 are connected to respective reception signal output terminals LNAOUT1, LNAOUT2, and LNAOUT3. A reception signal amplified by the low-noise amplifier 106 is output from a reception signal output terminal selected by the output terminal selection switch 109.

Power supply voltages are applied from a power terminal Vcc1 and a power terminal Vcc2 to the driver stage amplifier circuit 110 and the power stage amplifier circuit 111, respectively. The power amplifier control circuit 107 is connected to a power terminal VIO1, a control signal terminal SDATA1, and a clock terminal SCLK1. The power amplifier control circuit 107 controls the driver stage amplifier circuit 110 and the power stage amplifier circuit 111 on the basis of a digital control signal given to the control signal terminal SDATA1.

The low-noise amplifier control circuit 108 is connected to a power terminal VIO2, a control signal terminal SDATA2, and a clock terminal SCLK2. The low-noise amplifier control circuit 108 controls the low-noise amplifier 106 on the basis of a digital control signal given to the control signal terminal SDATA2.

The input switch 101, the band selection switch 102 for transmission, the antenna switch 104, the band selection switch 105 for reception, and the output terminal selection switch 109 are composed of CMOS transistors formed in the device layer 30 (FIG. 2) of the semiconductor device 10. The band selection switch 102 for transmission and the antenna switch 104, through which high-power high-frequency signals pass, are main heat sources.

Next, the excellent effects of the fourth embodiment will be described.

A high-frequency module according to the fourth embodiment includes the semiconductor device 10 according to the first embodiment, the second embodiment, or the third embodiment. Therefore, the heat dissipation efficiency from the transistor constituting the band selection switch 102 for transmission and the antenna switch 104, which are the main heat sources, is improved, and the temperature rise of the transistor can be suppressed. Further, the deterioration of the high-frequency characteristics of the band selection switch 102 for transmission and the antenna switch 104 due to the parasitic capacitance is suppressed.

An amount of heat generated from a transistor constituting the input switch 101, the low-noise amplifier 106, and the output terminal selection switch 109, through which high-power high-frequency signals does not pass, is smaller than an amount of heat generated from a transistor constituting the band selection switch 102 for transmission and the antenna switch 104. Therefore, the transistors constituting the input switch 101, the low-noise amplifier 106, and the output terminal selection switch 109 do not necessarily have to overlap with the bumps 70 or the heat transfer layer 50 (FIG. 4A) in plan view, but these transistors may overlap with the bumps 70 or the heat transfer layer 50.

Each of the above-described embodiments is exemplary, and it goes without saying that partial replacement or combination of configurations shown in different embodiments is possible. The same operation and effect due to the same configuration of a plurality of embodiments will not be sequentially referred to for each embodiment. Moreover, the present disclosure is not limited to the above-described embodiments. For example, it will be obvious to a person skilled in the art that various changes, improvements, combinations, and the like are possible.

For example, in each of the above-described embodiments, the heat transfer layer 50 is composed of a single layer, but the heat transfer layer 50 may be composed of a plurality of layers. In other words, the heat transfer layer 50 may include a plurality of layers formed of an insulating material having a thermal conductivity higher than a thermal conductivity of the insulating layer 20 on the surface opposite to the device layer 30 as viewed from the insulating layer 20. Here, each of the plurality of layers constituting the heat transfer layer 50 may be continuously disposed from a portion with overlapping the non-overlapping portion 31Y of the transistor 31 to a portion overlapping with at least one of the plurality of bumps 70.

In addition, in this case, the plurality of layers constituting the heat transfer layer 50 may be formed to include different materials. For example, in the plurality of layers constituting the heat transfer layer 50, the thermal conductivity of the insulating material forming the layer disposed at a position relatively close to the insulating layer 20 may be higher than the thermal conductivity of the insulating material forming the layer disposed at a position relatively far from the insulating layer 20. In this case, it is possible to improve the heat dissipation efficiency of the semiconductor device 10.

What is claimed is:

1. A semiconductor device comprising:
a device layer including at least one of transistors;
a plurality of bumps that are on one surface of the device layer;
an insulating layer that is on a surface of the device layer opposite to the surface having the plurality of bumps; and
a heat transfer layer that is in contact with a surface of the insulating layer opposite to a surface on which the device layer is disposed, and includes an insulating material having a thermal conductivity higher than a thermal conductivity of the insulating layer, wherein
when the device layer is viewed in plan view, one first transistor of the transistors includes a non-overlapping portion which is a portion not overlapping with the plurality of bumps, and the heat transfer layer is continuous from a portion overlapping with the non-overlapping portion to a portion overlapping with at least one of the plurality of bumps.

2. The semiconductor device according to claim 1, wherein
the heat transfer layer includes at least one material selected from a group consisting of diamond-like carbon, boron nitride, alumina, and aluminum nitride.

3. The semiconductor device according to claim 2, wherein
a thickness of the heat transfer layer is 580 nm or more.

4. The semiconductor device according to claim 1, wherein
the heat transfer layer is in contact with an entire surface of the insulating layer opposite to the surface on which the device layer is disposed.

5. The semiconductor device according to claim 1, further comprising:
a support substrate that is on a surface of the heat transfer layer opposite to a surface on which the insulating layer is disposed, is thicker than the heat transfer layer, and includes an insulating material having a thermal conductivity lower than a thermal conductivity of the heat transfer layer.

6. The semiconductor device according to claim 5, wherein
a thermal conductivity of the support substrate is 30 W/m·K or less.

7. The semiconductor device according to claim 1, wherein
when the device layer is viewed in plan view, the first transistor does not overlap with any of the plurality of bumps, and an entire region of the first transistor is the non-overlapping portion.

8. The semiconductor device according to claim 1, wherein
when the device layer is viewed in plan view, the first transistor includes an overlapping portion that overlaps with at least one of the plurality of bumps in a portion.

9. The semiconductor device according to claim 8, wherein
when the device layer is viewed in plan view, an area of the non-overlapping portion is larger than an area of the overlapping portion.

10. The semiconductor device according to claim 8, wherein
when the device layer is viewed in plan view, at least one of the plurality of bumps does not overlap with the first transistor and overlaps with the heat transfer layer.

11. The semiconductor device according to claim 1, wherein
the insulating layer includes a single layer or a plurality of layers.

12. The semiconductor device according to claim 1, wherein
the heat transfer layer includes a single layer or a plurality of layers.

13. The semiconductor device according to claim 12, wherein
the heat transfer layer includes a plurality of layers, and
a thermal conductivity of an insulating material of a layer at a position relatively close to the insulating layer among the plurality of layers of the heat transfer layer is higher than a thermal conductivity of an insulating material of a layer at a predetermined position from the insulating layer among the plurality of layers.

14. The semiconductor device according to claim 2, wherein
the heat transfer layer is in contact with an entire surface of the insulating layer opposite to the surface on which the device layer is disposed.

15. The semiconductor device according to claim 2, further comprising:
a support substrate that is on a surface of the heat transfer layer opposite to a surface on which the insulating layer is disposed, is thicker than the heat transfer layer, and includes an insulating material having a thermal conductivity lower than a thermal conductivity of the heat transfer layer.

16. The semiconductor device according to claim 2, wherein
when the device layer is viewed in plan view, the first transistor does not overlap with any of the plurality of bumps, and an entire region of the first transistor is the non-overlapping portion.

17. The semiconductor device according to claim 2, wherein
when the device layer is viewed in plan view, the first transistor includes an overlapping portion that overlaps with at least one of the plurality of bumps in a portion.

18. The semiconductor device according to claim 9, wherein
when the device layer is viewed in plan view, at least one of the plurality of bumps does not overlap with the first transistor and overlaps with the heat transfer layer.

19. The semiconductor device according to claim 2, wherein
the insulating layer includes a single layer or a plurality of layers.

20. The semiconductor device according to claim 2, wherein
the heat transfer layer includes a single layer or a plurality of layers.
